(19) United States
(12) Patent Application Publication
(10) Pub. No.: US 2026/0100679 A1
(43) Pub. Date: Apr. 9, 2026

(54) AMPLIFICATION CIRCUIT AND CONTROL METHOD THEREOF

(71) Applicant: RichWave Technology Corp., Taipei City (TW)

(72) Inventor: Hsuan-Ming Liu, Taipei City (TW)

(73) Assignee: RichWave Technology Corp., Taipei City (TW)

(21) Appl. No.: 18/953,106

(22) Filed: Nov. 20, 2024

(30) Foreign Application Priority Data
Oct. 7, 2024 (TW) 113138110

(51) Int. Cl. H03F 1/26; H03F 1/52; H03F 1/56; H03F 3/21

(52) U.S. Cl. CPC H03F 1/26; H03F 1/523; H03F 1/565; H03F 3/21; H03F 2200/222; H03F 2200/451

(57) ABSTRACT

An amplification circuit includes an input terminal, an output terminal, a first path circuit and a second path circuit. The input terminal would receive an input signal. The output terminal would output an output signal corresponding to the input signal. The first path circuit includes a co-design circuit, an amplifier circuit, a second matching element, and an electrical overstress circuit. The co-design circuit includes a first matching element. A first terminal of the co-design circuit is coupled to the input terminal. The electrical overstress circuit and the second matching element are coupled to a second terminal of the co-design circuit. The amplifier circuit is coupled between the second terminal of the co-design circuit and the output terminal. The second path circuit is coupled between the input terminal and the output terminal. The co-design circuit provides a first impedance in a first mode and a second impedance in a second mode.

### TECHNICAL FIELD

The disclosure relates to an amplification circuit and a control method, and more particularly, an amplification circuit comprising a first path circuit and a second path circuit, and a control method thereof.

### BACKGROUND

With the widespread application of electronic products, safety and reliability standards have become critical considerations in design. When the input power from an external signal exceeds a certain threshold, it can potentially damage the internal circuits of electronic devices, such as causing amplifier failure. There is still a lack of suitable solutions in the field to effectively protect electronic devices.

For communication devices, the noise figure (NF) must also be considered during protection to avoid high noise figures, which can negatively impact the signal-to-noise ratio and result in a decline in communication quality. Currently, there are still no suitable solutions in the field to effectively reduce the noise figure.

### SUMMARY

An embodiment provides an amplification circuit comprising an input terminal, an output terminal, a first path circuit, and a second path circuit. The input terminal is configured to receive an input signal. The output terminal is configured to output an output signal corresponding to the input signal. The first path circuit comprises a co-design circuit, an amplifier circuit, a second matching element, and an electrical overstress circuit. The co-design circuit comprises a first terminal coupled to the input terminal, a second terminal, and a first matching element. The first matching element comprises a first terminal coupled to the first terminal of the co-design circuit, and a second terminal coupled to the second terminal of the co-design circuit. The amplifier circuit is configured to amplify the input signal. The amplifier circuit comprises a first terminal coupled to the second terminal of the co-design circuit, and a second terminal coupled to the output terminal. The second matching element comprises a first terminal coupled to the first terminal of the amplifier circuit, and a second terminal coupled to a reference voltage terminal. The electrical overstress circuit comprises a first terminal coupled between the second terminal of the co-design circuit and the first terminal of the amplifier circuit, and a second terminal coupled to the reference voltage terminal. The first terminal of the electrical overstress circuit is coupled between the second terminal of the co-design circuit and the first terminal of the second matching element. The second path circuit comprises a first terminal coupled to the input terminal, and a second terminal coupled to the output terminal. The co-design circuit provides a first impedance in a first mode, and the co-design circuit provides a second impedance in a second mode.

Another embodiment provides a control method for an amplification circuit. The amplification circuit comprises an input terminal, an output terminal, a first path circuit, and a second path circuit. The first path circuit comprises a co-design circuit, an electrical overstress circuit, and an amplifier circuit. The control method comprises using the input terminal to receive an input signal; using the output terminal to output an output signal corresponding to the input signal; turning off a switch of the co-design circuit to control the amplification circuit to enter an amplification mode to transmit and process the input signal through the co-design circuit to generate the output signal, wherein a matching element of the co-design circuit is used to provide a matching impedance to the amplifier circuit; turning on the switch of the co-design circuit to control the amplification circuit to enter a bypass mode or a power amplification mode to transmit and process the input signal through the second path circuit to generate the output signal, wherein the matching element of the co-design circuit resonates to provide a high impedance; and turning on the electrical overstress circuit to control the amplification circuit to enter an electrical overstress mode to transmit a signal to a reference voltage terminal through the co-design circuit.

### BRIEF DESCRIPTION OF THE DRAWINGS

FIG. 1 shows an amplification circuit according to an embodiment.

FIG. 2 shows a co-design circuit according to an embodiment.

FIG. 3 shows a co-design circuit according to another embodiment.

FIG. 4 shows an amplification circuit according to an embodiment.

FIG. 5 shows a switch according to an embodiment.

FIG. 6 shows an electrical overstress circuit according to an embodiment.

FIG. 7 shows an equivalent diagram when the electrical overstress circuit performs reverse clamping according to an embodiment.

FIG. 8 shows an equivalent diagram when the electrical overstress circuit performs forward clamping according to an embodiment.

FIG. 9 shows a co-design circuit and an electrical overstress circuit according to an embodiment.

FIG. 10 shows an electrical overstress circuit according to another embodiment.

FIG. 11 shows transistors of the switch and the electrical overstress circuit according to an embodiment.

FIG. 12 shows a second path circuit including an attenuation circuit according to an embodiment.

FIG. 13 shows a second path circuit including a power amplification circuit according to another embodiment.

FIG. 14 shows an electrical overstress circuit according to another embodiment.

FIG. 15 shows a flowchart of a control method for an amplification circuit according to an embodiment.

FIG. 16 shows a state transition waveform diagram where the electrical overstress circuit is used for protection according to an embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

To effectively protect electronic devices and maintain their performance, solutions are provided according to embodiments as described below. In this document, when an element A is mentioned as being coupled to an element B, it can be directly coupled, electrically connected, or indirectly coupled through other elements. The size of a transistor described herein can be defined using the gate width, width/length ratio (W/L ratio), and/or the number of fingers. When two values are mentioned as being substantially the same, it means that the difference between the two values can be less than 10%, 5%, or 1% of each value.

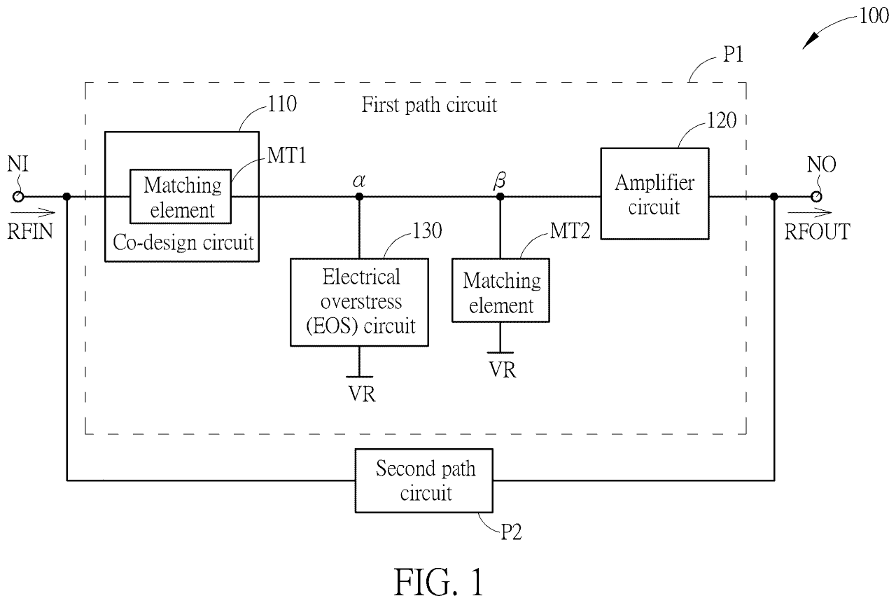

FIG. 1 shows an amplification circuit 100 according to an embodiment. The amplification circuit 100 can comprise an input terminal NI, an output terminal NO, a first path circuit P1, and a second path circuit P2.

The input terminal NI is used to receive an input signal RFIN, and the output terminal NO is used to output an output signal RFOUT corresponding to the input signal RFIN.

The first path circuit P1 can comprise a co-design circuit 110, an amplifier circuit 120, a matching element MT2, and an electrical overstress (EOS) circuit 130.

The co-design circuit 110 can include a first terminal, a second terminal, and a matching element MT1, where the first terminal of the co-design circuit 110 can be coupled to the input terminal NI. The matching element MT1 can include a first terminal and a second terminal, where the first terminal of the matching element MT1 can be coupled to the first terminal of the co-design circuit 110, and the second terminal of the matching element MT1 can be coupled to the second terminal of the co-design circuit 110.

The amplifier circuit 120 can be used to amplify the input signal RFIN. The amplifier circuit 120 can include a first terminal and a second terminal, where the first terminal of the amplifier circuit 120 can be coupled to the second terminal of the co-design circuit 110, and the second terminal of the amplifier circuit 120 can be coupled to the output terminal NO.

The matching element MT2 can include a first terminal and a second terminal, where the first terminal of the matching element MT2 can be coupled to the first terminal of the amplifier circuit 120, and the second terminal of the matching element MT2 can be coupled to a reference voltage terminal VR to receive a reference voltage. The reference voltage can be a ground voltage or an appropriate and stable predetermined reference voltage.

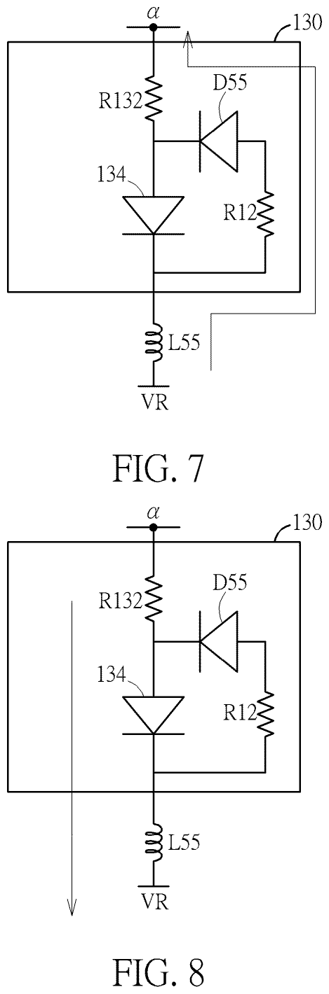

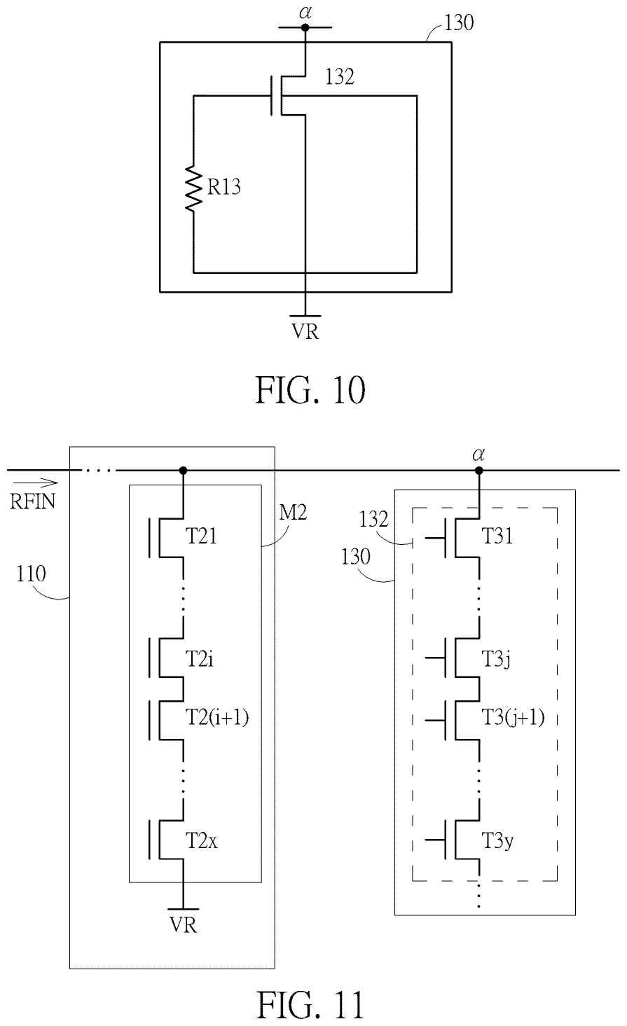

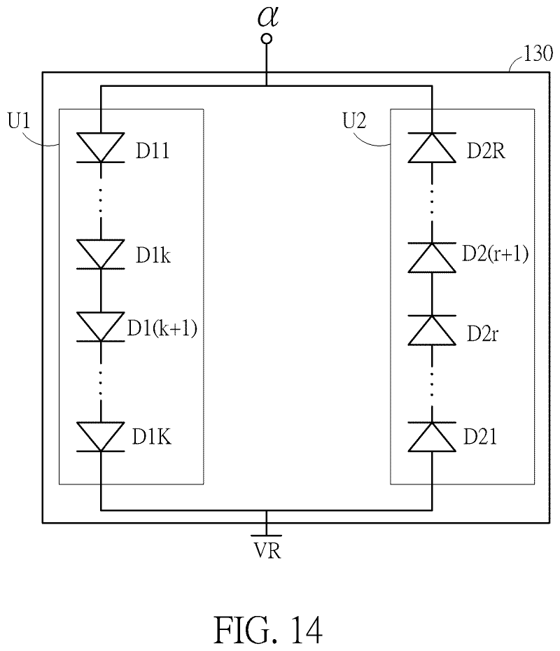

The electrical overstress circuit 130 can include a first terminal and a second terminal, where the first terminal of the electrical overstress circuit 130 can be coupled between the second terminal of the co-design circuit 110 and the first terminal of the amplifier circuit 120, and the second terminal of the electrical overstress circuit 130 can be coupled to the reference voltage terminal VR. As shown in FIG. 1, in an embodiment, the first terminal of the electrical overstress circuit 130 can be coupled between the second terminal of the co-design circuit and the first terminal of the matching element MT2. As shown in FIG. 1, the first terminal of the electrical overstress circuit 130 can be coupled to a node α. The electrical overstress circuit 130 can be used to adjust the voltage level of node α, ensuring that it does not become too high and thus preventing damage to the amplifier circuit 120. Examples of the electrical overstress circuit 130 will be illustrated in FIG. 6, FIG. 7, FIG. 8, FIG. 10, and FIG. 14.

The second path circuit P2 can include a first terminal and a second terminal, where the first terminal of the second path circuit P2 can be coupled to the input terminal NI, and the second terminal of the second path circuit P2 can be coupled to the output terminal NO.

The co-design circuit 110 can provide a first impedance in a first mode and a second impedance, different from the first impedance, in a second mode. In an embodiment, the first impedance can be lower than the second impedance. In an embodiment, the first path circuit P1 and the second path circuit P2 can be coupled in parallel.

For example, the matching element MT1 can include a capacitor, which can be a series capacitor. The matching element MT2 can include an inductor, which can be a shunt inductor. The amplifier circuit 120 can include a low noise amplifier (LNA).

For example, in the first mode, the input signal RFIN can be transmitted through the first path circuit P1 and processed to generate the output signal RFOUT. In the second mode, the input signal RFIN can be transmitted through the second path circuit P2 and processed to generate the output signal RFOUT.

In an embodiment, when the input power of the input signal RFIN is lower, it can be transmitted and processed through the first path circuit P1 for amplification. When the input power of the input signal RFIN is higher, it can be transmitted and processed through the second path circuit P2 for bypass or amplification at a lower gain. Therefore, the power of the signal entering the first path circuit P1 can be less than the power of the signal entering the second path circuit P2. In an embodiment, the signal entering the first path circuit P1 has a first power, and the signal entering the second path circuit P2 has a second power, and the first power can be less than the second power.

As shown in FIG. 1, the matching element MT1 and the matching element MT2 can together form a part of the input impedance matching circuit of the amplifier circuit 120. Adjusting the input impedance matching circuit can set the input impedance of the amplification circuit 100 to a predetermined matching value to improve power transfer efficiency, enhance the signal-to-noise ratio (SNR), reduce signal reflection, and increase signal integrity, thereby improving the performance of handling radio-frequency (RF) signals.

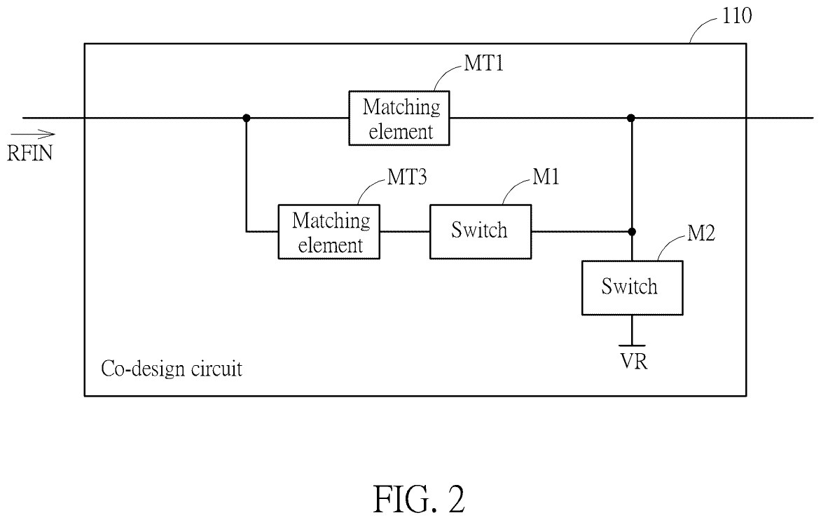

FIG. 2 shows the co-design circuit 110 according to an embodiment. In addition to the aforementioned matching element MT1, the co-design circuit 110 can also include a matching element MT3 and a switch M1. The matching element MT3 and the switch M1 can be coupled in series between the first terminal and the second terminal of the co-design circuit 110. In an embodiment, the matching element MT3 can include an inductor.

As shown in FIG. 2, the co-design circuit 110 can also include a switch M2. The switch M2 can include a first terminal and a second terminal, where the first terminal of the switch M2 can be coupled to the second terminal of the co-design circuit 110, and the second terminal of the switch M2 can be coupled to the reference voltage terminal VR.

Each of the switches M1 and M2 can include a transistor and/or a switch circuit that can be controlled to be in conducting and non-conducting states. As shown in FIG. 1, a node α can be coupled to the electrical overstress circuit 130, and a node β can be coupled to the matching element MT2. The node α can be located between the co-design circuit 110 and the node β, and the node β can be located between the node α and the amplifier circuit 120.

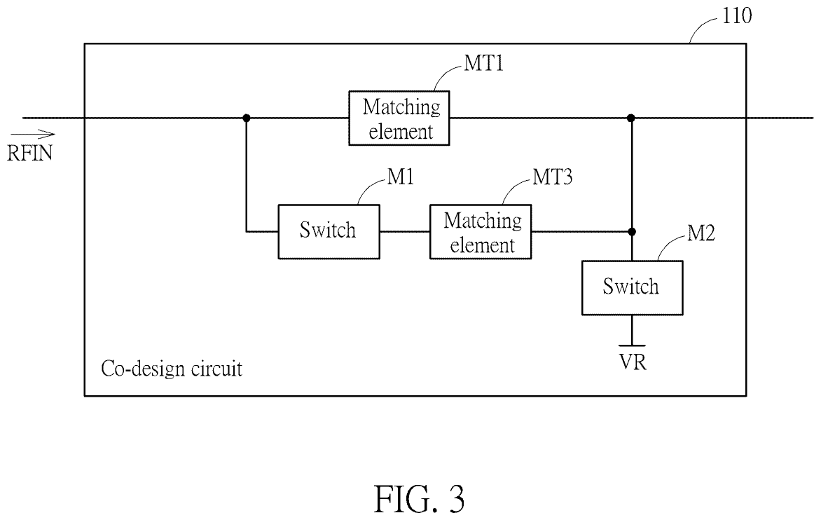

In FIG. 2, the matching element MT3 can be closer to the first terminal of the co-design circuit 110, and the switch M1 can be closer to the second terminal of the co-design circuit 110. In one embodiment, the positions of the matching element MT3 and the switch M1 in FIG. 2 can be swapped. FIG. 3 shows a schematic diagram of the co-design circuit 110 according to another embodiment. The similarities between FIG. 3 and FIG. 2 will not be reiterated. In FIG. 3, the switch M1 can be closer to the first terminal of the co-design circuit 110, and the matching element MT3 can be closer to the second terminal of the co-design circuit 110.

In FIG. 1 to FIG. 3, when the first path circuit P1 is enabled, the amplifier circuit 120 can be used to amplify the signal, and the amplification circuit 100 can operate in an amplification mode. In this amplification mode, the switch M1 of the co-design circuit 110 can be turned off, the switch M2 can be turned off, and the input signal RFIN can be transmitted and processed through the first path circuit P1 to generate the output signal RFOUT. For example, when the first path circuit P1 is enabled, the amplification circuit 100 can operate in a low noise amplification mode (LNA mode), and the co-design circuit 110 is in the first mode.

In FIG. 1 to FIG. 3, when the second path circuit P2 is enabled, the amplifier circuit 120 may not be used. If the second path circuit P2 does not amplify the signal, the amplification circuit 100 can operate in a bypass mode. If the second path circuit P2 amplifies the signal, the amplification circuit 100 can operate in a power amplification (PA) mode. In the bypass mode or the power amplification mode, the switch M1 of the co-design circuit 110 can be turned on, the switch M2 can be turned on, the input signal RFIN can be transmitted and processed through the second path circuit P2 to generate the output signal RFOUT, and the co-design circuit 110 is in the second mode.

The above operations can be as shown in Table-1.

TABLE 1

| Condition | State |
|---|---|
| The first path | The amplification circuit can be operated in the |
| circuit P1 is | amplification mode. |
| enabled. | The second path circuit P2 can be disabled. |
| | The switch M1 of the co-design circuit 110 can be |
| | turned off. |
| | The switch M2 of the co-design circuit 110 can be |
| | turned off. |
| | The co-design circuit 110 can provide the first |
| | impedance. |
| The second path | The amplification circuit can be operated in the |
| circuit P2 is | bypass mode, or the power amplification mode. |
| enabled. | The first path circuit P1 can be disabled. |
| | The switch M1 of the co-design circuit 110 can be |
| | turned on. |
| | The switch M2 of the co-design circuit 110 can be |
| | turned on. |
| | The co-design circuit 110 can provide the second |
| | impedance. |
| | (The first impedance can be less than the second |
| | impedance.) |

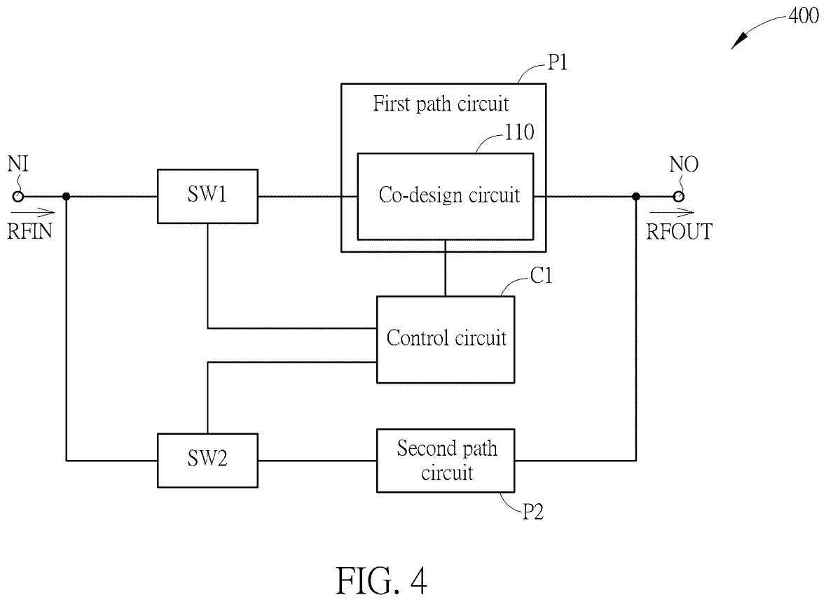

FIG. 4 shows an amplification circuit 400 according to another embodiment. The amplification circuit 400 can include the input terminal NI, the output terminal NO, a switch SW1, a switch SW2, the first path circuit P1, the second path circuit P2, and a control circuit C1. The differences between FIG. 4 and FIG. 1 are that FIG. 4 can additionally include the switch SW1, the switch SW2, and the control circuit C1. The first path circuit P1 in FIG. 4 can include the amplifier circuit 120, the matching element MT2, and the electrical overstress circuit 130, but these are omitted for simplicity.

In FIG. 4, the first path circuit P1 can include the co-design circuit 110, and the co-design circuit 110 can be as shown in FIG. 2 or FIG. 3. Similar to FIG. 1, the input terminal NI can receive the input signal RFIN, and the output terminal NO can output the output signal RFOUT corresponding to the input signal RFIN. The switch SW1 can be coupled between the input terminal NI and the first path circuit P1 to control whether the signal is transmitted and processed through the first path circuit P1. The switch SW2 can be coupled between the input terminal NI and the second path circuit P2 to control whether the signal is transmitted and processed through the second path circuit P2. The control circuit C1 can control the switch SW1, the switch SW2, and the co-design circuit 110 to enable and/or disable the first path circuit P1 and the second path circuit P2. The operation of the amplification circuit 400 can be as shown in Table-2. In one embodiment, the control circuit C1 can control the control terminal of the switch M1 and the control terminal of the switch M2 of the co-design circuit 110 to enable and/or disable the first path circuit P1 and the second path circuit P2.

TABLE 2

| Condition | State |
|---|---|
| The first path | The switch SW1 can be turned on. |
| circuit P1 is | The switch SW2 can be turned off. |
| enabled. | The second path circuit P2 can be disabled. |
| | The switch M1 of the co-design circuit 110 |
| | can be off. |
| | The switch M2 of the co-design circuit 110 |
| | can be off. |
| | The co-design circuit 110 can provide the first |
| | impedance. |
| The second path | The first path circuit P1 can be disabled. |
| circuit P2 is | The switch SW1 can be turned off. |
| enabled. | The switch SW2 can be turned on. |
| | The switch M1 of the co-design circuit 110 |
| | can be turned on. |
| | The switch M2 of the co-design circuit 110 |
| | can be turned on. |
| | The matching element MT1, the matching |
| | element MT3, and the switch M1 of the co-design |
| | circuit 110 can resonate to provide the second |
| | impedance |
| | (The first impedance can be less than the |
| | second impedance.) |

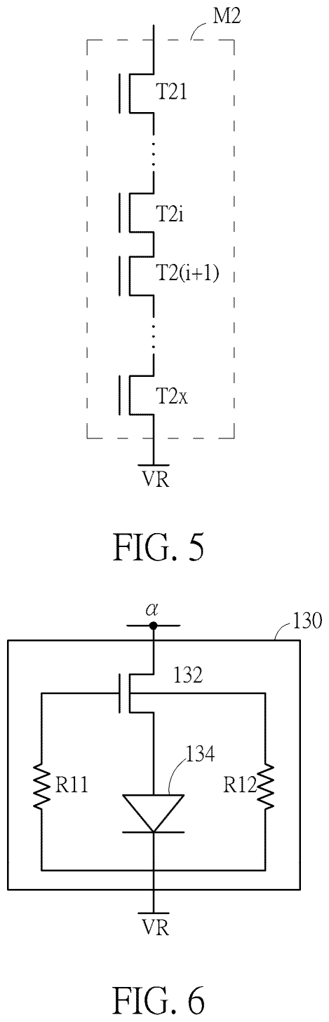

FIG. 5 shows the switch M2 according to an embodiment. The switch M2 can include x transistors T21 to T2x, and each transistor can include a first terminal and a second terminal, where a second terminal of an i-th transistor can be coupled to a first terminal of an (i+1)-th transistor, i and x are positive integers, and 0<i<x.

FIG. 6 shows the electrical overstress circuit 130 according to an embodiment. The electrical overstress circuit 130 can include a transistor 132 and a diode 134. The transistor 132 can include a first terminal, a second terminal, and a control terminal, where the first terminal of the transistor 132 can be coupled to the first terminal of the electrical overstress circuit 130, and the control terminal of the transistor 132 can be coupled to the reference voltage terminal VR. The diode 134 can include an anode terminal and a cathode terminal, where the anode terminal can be coupled to the second terminal of the transistor 132, and the cathode terminal can be coupled to the reference voltage terminal VR. In one embodiment, the transistor 132 can be an n-type field-effect transistor (N-MOSFET).

In an embodiment, the electrical overstress circuit 130 can include a resistor R11. The resistor R11 can include a first terminal and a second terminal, where the first terminal of the resistor R11 can be coupled to the control terminal of the transistor 132, and the second terminal of the resistor R11 can be coupled to the cathode terminal of the diode 134.

In an embodiment, the electrical overstress circuit 130 can include a resistor R12. The resistor R12 can include a first terminal and a second terminal, where the first terminal of the resistor R12 can be coupled to the body terminal of the transistor 132, and the second terminal of the resistor R12 can be coupled to the reference voltage terminal VR. Therefore, the body terminal of the transistor 132 can be coupled to the reference voltage terminal VR through the resistor R12.

In FIG. 6, the diode 134 can be optionally included or omitted, the resistor R11 can be optionally included or omitted, and the resistor R12 can be optionally included or omitted. The resistor R12 can block the direct current (DC) portion of the signal and can be a choke resistor.

In an embodiment, the electrical overstress circuit 130 can include the transistor 132, the diode 134, the resistor R11, and the resistor R12.

In FIG. 6, when the voltage level of the node α is a positive voltage, the electrical overstress circuit 130 can perform forward clamping operations. When the voltage level of the node α is a negative voltage, the electrical overstress circuit 130 can perform reverse clamping operations.

### Regarding the Reverse Clamping Operation:

When the electrical overstress circuit 130 performs a reverse clamping operation, it can be as follows. FIG. 7 shows an equivalent diagram of the electrical overstress circuit 130 during the reverse clamping operation according to an embodiment. FIG. 7 is not a completely accurate model but is used to explain the principle. A diode D55 can be an equivalent diode between the body terminal and the second terminal (e.g., source terminal) in the transistor 132. An inductor L55 can be corresponding to the inductance of the bonding wire coupled to the reference voltage terminal VR. When the voltage level of the node α is a negative voltage, the signal can flow sequentially from the inductor L55, the resistor R12, and the body terminal to the second terminal (via diode D55) of the transistor 132 to the node α. In FIG. 7, the diode D55 and the resistor R12 can be used to regulate the voltage level of the node α to enter the safe voltage range.

### Regarding the Forward Clamping Operation:

When the electrical overstress circuit 130 performs a forward clamping operation, it can be as follows. FIG. 8 shows an equivalent diagram of the electrical overstress circuit 130 during the forward clamping operation according to an embodiment. FIG. 8 is not a completely accurate model but is used to explain the principle. When the voltage level of the node α is a positive voltage and the voltage is higher, the transistor 132 may experience breakdown or coupling conduction, and the transistor 132 is not completely turned off but has conducting characteristics, resulting in a conducting resistor R132. The current can flow from the node α through the conducting resistor R132 and the diode 134 to the reference voltage terminal VR. In FIG. 8, the conducting resistor R132 is an equivalent conducting resistor of the transistor 132. The inductor L55 can be corresponding to the inductance of the bonding wire coupled to the reference voltage terminal VR. In FIG. 8, the diode 134 and the equivalent resistance R132 can be used to regulate the voltage level of the node α to enter the safe voltage range.

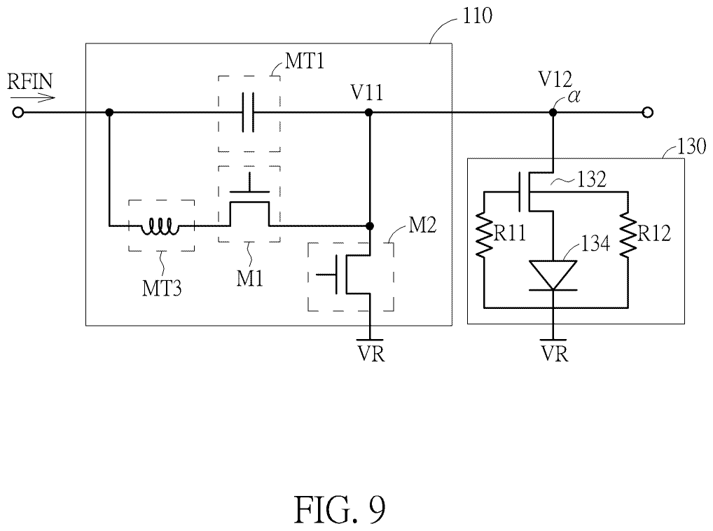

FIG. 9 shows a diagram of the co-design circuit 110 and the electrical overstress circuit 130 according to an embodiment. FIG. 9 is an example used to explain the principle, and embodiments are not limited thereto. In FIG. 9, the matching element MT1 can include a capacitor, the matching element MT3 can include an inductor, the switches M1 and M2 can include transistors, and the electrical overstress circuit 130 can include the transistor 132 and the diode 134. In FIG. 9, voltages V11 and V12 can be substantially the same. Due to the high operating speed of the electrical overstress circuit 130, for example, the operating time can be less than 20 nanoseconds (nsec), when the voltage V12 is controlled by the clamping operation to a safe voltage level, the voltage V11 can also be immediately controlled by the clamping operation, so the voltage V11 will not be too high, for example, the voltage V11 can be less than 3 volts. Therefore, the voltage V11 will not exceed the predetermined voltage, so the voltage of the transistor of the switch M2 will not exceed the breakdown voltage, thus avoiding damage to the switch M2. The transistor 132 can be a field-effect transistor (FET) or a suitable transistor. Due to the small equivalent capacitance of the transistor 132, and the further reduced equivalent capacitance when the transistor 132 is coupled in series with other components, the transistor 132 and the diode 134 can have a lower parasitic capacitance value. The electrical overstress circuit 130 can perform clamping operations, provide isolation, and avoid unexpected noise figure (NF) increases. FIG. 10 shows the electrical overstress circuit 130 according to another embodiment. The electrical overstress circuit 130 in FIG. 10 can include the transistor 132. The transistor 132 of FIG. 10 can include a first terminal, a second terminal, and a control terminal, where the first terminal of the transistor 132 can be coupled to the first terminal of the electrical overstress circuit 130, and the second terminal and the control terminal of the transistor 132 can be coupled to the reference voltage terminal VR. In an embodiment, the second terminal of the transistor 132 can be directly coupled to the reference voltage terminal VR.

In an embodiment, the electrical overstress circuit 130 in FIG. 10 can include a resistor R13. The resistor R13 can include a first terminal and a second terminal, where the first terminal of the resistor R13 can be coupled to the control terminal of the transistor 132, and the second terminal of the resistor R13 can be coupled to the second terminal of the transistor 132. In an embodiment, as shown in FIG. 10, the body terminal of the transistor 132 can be coupled to the reference voltage terminal VR.

In FIG. 1 to FIG. 10, the transistor of the switch M2 can have a first size, and the transistor 132 of the electrical overstress circuit 130 can have a second size, and the second size can be larger than the first size. In an embodiment, the first size can be corresponding to a first width/length ratio, the second size can be corresponding to a second width/length ratio, and the ratio of the second width/length ratio to the first width/length ratio can be greater than 5.

In another embodiment, the transistor 132 of the electrical overstress circuit 130 and the transistor of the switch M2 can have the same width-to-length ratio. The transistor 132 of the electrical overstress circuit 130 can be formed by p semiconductor components, for example, formed by p semiconductor components coupled in parallel. The transistor of the switch M2 can be formed by q semiconductor components, for example, formed by q semiconductor components coupled in parallel. Here, p and q can be integers greater than 0, and p>q. For example, the first size can be 100 um/0.5 um with a corresponding M (number of components in parallel) of 5, and the second size can be 100 um/0.5 um with a corresponding M (number of components in parallel) of 1. In one embodiment, the aforementioned semiconductor component is a transistor. Each semiconductor component of the transistor of the electrical overstress circuit 130 can be the same as each semiconductor component of the transistor of the switch M2.

The design described above helps prevent the switch M2 from being damaged when the signal intensity (or amplitude) is high. To avoid damaging the switch M2, the on-resistance (Ron) of the transistor 132 in the electrical overstress circuit 130 should be less than the resistance of the switch M2.

The number of stacked transistors in the switch M2 (as shown in FIG. 5) can increase the reliability of the switch M2. Additionally, the number of parallel components in the transistor 132 of the electrical overstress circuit 130 can be greater than the number of parallel components in the transistor of the switch M2, to enhance the reliability of the device. For example, if the switch M2 includes predetermined semiconductor components with a gate width and gate length of 5 μm and 2 um (denoted as 5 u/2 u), the transistor 132 of the electrical overstress circuit 130 can include five predetermined semiconductor components (denoted as 5 u/2 u*5).

FIG. 11 shows the switch M2 of the co-design circuit 110 and the transistor 132 of the electrical overstress circuit 130 according to an embodiment. The switch M2 can include x transistors T21 to T2x. Each of the transistors T21 to T2x can include a first terminal and a second terminal. A second terminal of the i-th transistor T2i can be coupled to a first terminal of the (i+1)-th transistor T2(i+1). Here, i and x can be positive integers, and 0<i<x. The switch M2 in FIG. 11 can be similar to that shown in FIG. 5. In FIG. 11, the transistor 132 of the electrical overstress circuit 130 can be formed by y transistors T31 to T3y. Each of the transistors T31 to T3y can include a first terminal and a second terminal. A second terminal of the j-th transistor T3j can be coupled to a first terminal of the (j+1)-th transistor T3(j+1). Here, j and y can be positive integers, and 0<j<y. In FIG. 11, x>y. In other words, the switch M2 can include more stacked transistors than the transistor 132 of the electrical overstress circuit 130. In an embodiment, the equivalent resistance of the switch M2 can be greater than the equivalent resistance of the transistor 132 of the electrical overstress circuit 130.

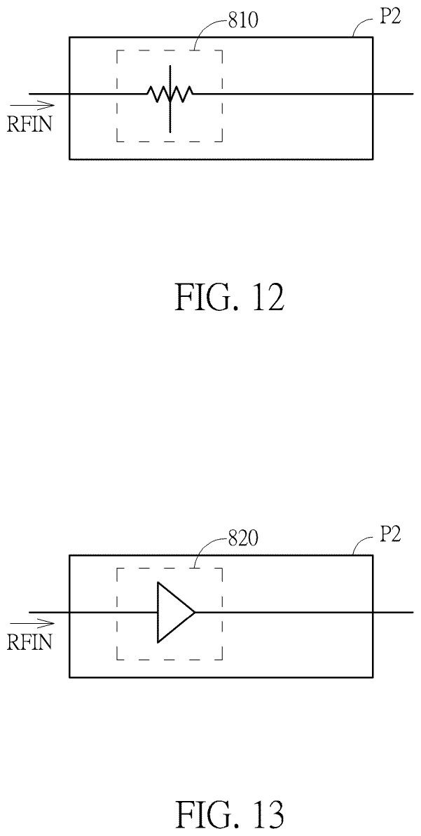

FIG. 12 shows the second path circuit P2 including an attenuation circuit 810 according to an embodiment. The attenuation circuit 810 can be used to attenuate the input signal RFIN. The attenuation circuit 810 can include a first terminal and a second terminal. The first terminal of the attenuation circuit 810 can be coupled to the first terminal of the second path circuit P2, and the second terminal of the attenuation circuit 810 can be coupled to the second terminal of the second path circuit P2. When the intensity of the input signal RFIN is high, the input signal RFIN can be transmitted and processed through the second path circuit P2 instead of the first path circuit P1, where the attenuation circuit 810 can reduce the intensity of the input signal RFIN as needed.

FIG. 13 shows the second path circuit P2 including a power amplification circuit 820 according to another embodiment. The power amplification circuit 820 can be used to amplify the input signal RFIN. The power amplification circuit 820 can include a first terminal and a second terminal. The first terminal of the power amplification circuit 820 can be coupled to the first terminal of the second path circuit P2, and the second terminal of the power amplification circuit 820 can be coupled to the second terminal of the second path circuit P2. When the input signal RFIN needs to be amplified, the input signal RFIN can be transmitted and processed through the second path circuit P2, where the power amplification circuit 820 can increase the intensity of the input signal RFIN as needed.

FIG. 14 shows the electrical overstress circuit 130 according to another embodiment. The electrical overstress circuit 130 can include a first diode string U1 and a second diode string U2.

The first diode string U1 can include K diodes D11 to D1K. In the diodes D11 to D1K, the cathode terminal of the k-th diode D1k can be coupled to the anode terminal of the (k+1)-th diode D1(k+1). The anode terminal of the first diode D11 can be coupled to the first terminal of the electrical overstress circuit 130. The cathode terminal of the K-th diode D1K can be coupled to the second terminal of the electrical overstress circuit 130. Here, K and k can be integers, and 1≤k≤(K−1).

The second diode string U2 can include R diodes D21 to D2R. In the diodes D21 to D2R, the cathode terminal of the r-th diode D2r can be coupled to the anode terminal of the (r+1)-th diode D2(r+1). The anode terminal of the first diode D21 can be coupled to the second terminal of the electrical overstress circuit 130. The cathode terminal of the R-th diode D2R can be coupled to the first terminal of the electrical overstress circuit 130. Here, R and r can be integers, and 1≤r≤(R−1).

Using the electrical overstress circuit 130 with the various structures described above can protect the amplifier circuit 120 in FIG. 1, such as a low noise amplifier.

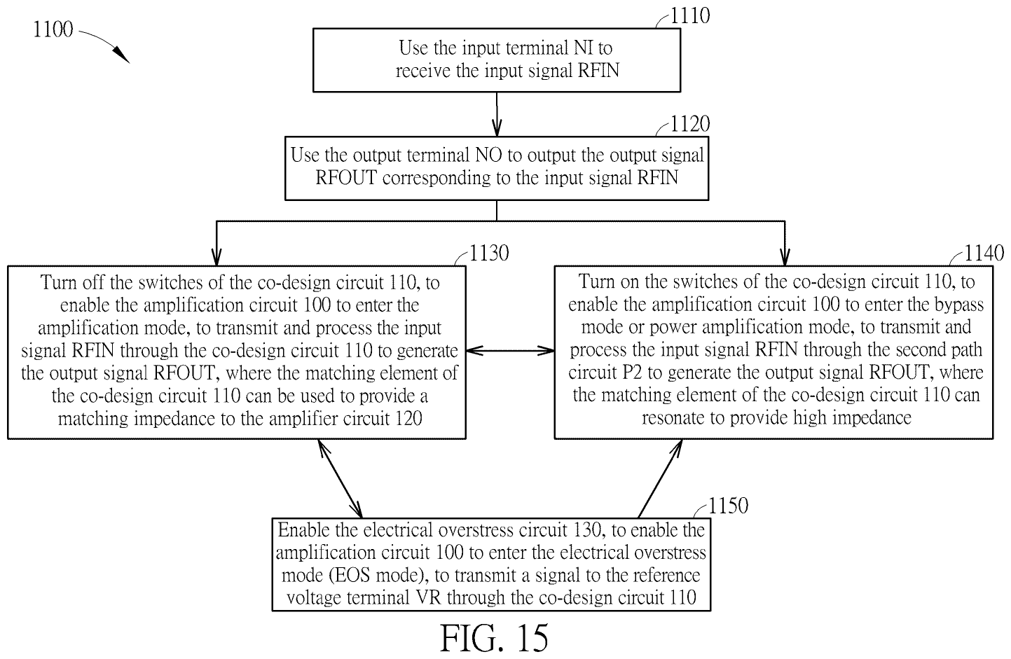

FIG. 15 shows a flowchart of a control method 1100 for the amplification circuit 100 according to an embodiment. As shown in FIG. 1 to FIG. 14, the amplification circuit 100 can include the input terminal NI, the output terminal NO, the first path circuit P1, and the second path circuit P2. The first path circuit P1 can include the co-design circuit 110, the electrical overstress circuit 130, the matching element MT1, and the amplifier circuit 120. The control method 1100 can include the following steps.

Step 1110: Use the input terminal NI to receive the input signal RFIN;

Step 1120: Use the output terminal NO to output the output signal RFOUT corresponding to the input signal RFIN;

Step 1130: Turn off the switches of the co-design circuit 110 (e.g., switches M1 and M2 in FIG. 2), to enable the amplification circuit 100 to enter the amplification mode (e.g., LNA mode), to transmit and process the input signal RFIN through the co-design circuit 110 to generate the output signal RFOUT, where the matching element of the co-design circuit 110 (e.g., matching element MT1 in FIG. 1) can be used to provide a matching impedance to the amplifier circuit 120;

Step 1140: Turn on the switches of the co-design circuit 110 (e.g., switches M1 and M2 in FIG. 2), to enable the amplification circuit 100 to enter the bypass mode or power amplification (PA) mode, to transmit and process the input signal RFIN through the second path circuit P2 to generate the output signal RFOUT, where the matching element of the co-design circuit 110 (e.g., matching element MT1 in FIG. 1) can resonate to provide high impedance; and

Step 1150: Enable the electrical overstress circuit 130, to enable the amplification circuit 100 to enter the electrical overstress mode (EOS mode), to transmit a signal to the reference voltage terminal VR through the co-design circuit 110.

In FIG. 15, in an embodiment, the sequence of Step 1130, Step 1140, and Step 1150 is not limited to being performed in the order of FIG. 15 but can be controlled according to the needs. In an embodiment, Step 1130 or Step 1140 can be entered as needed. After Step 1130, Step 1140 or Step 1150 can be entered as needed. After Step 1140, Step 1130 can be entered as needed. After Step 1150, Step 1130 or Step 1140 can be entered as needed. The above process can be performed and adjusted according to actual needs, and still falls within the scope of the embodiments.

In the above steps, the switches of the co-design circuit 130 (e.g., switches M1 and M2 in FIG. 2) can be controlled by digital signals.

In Step 1130 and Step 1140, the matching element of the co-design circuit 110 (e.g., matching element MT1 in FIG. 1) can be a series capacitor.

In Step 1140, regarding the high impedance generated by resonance, for example, the matching element MT1, the switch M1, and the matching element MT3 of the co-design circuit 110 shown in FIG. 3 can resonate to generate high impedance.

In Step 1150, a threshold can be set. In response to the intensity (or amplitude) of the input signal RFIN exceeds the threshold, the electrical overstress circuit 130 can be enabled to protect the circuit.

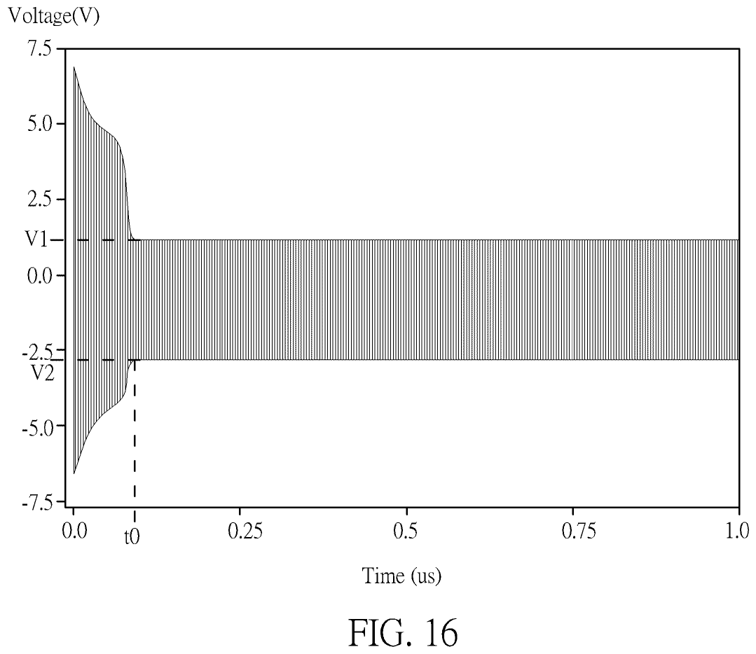

FIG. 16 shows a transient waveform diagram for protection using the electrical overstress circuit 130 in FIG. 6 according to an embodiment. The horizontal axis in FIG. 16 represents the time axis, with units in microseconds (us), and the vertical axis represents the voltage level at the first terminal of the electrical overstress circuit 130 (i.e., the node α in FIG. 1), with units in volts (V). FIG. 16 is a waveform diagram, but due to the high signal frequency, the waveform details are not easily discernible in the diagram. However, changes in signal intensity (or amplitude) can be observed.

At time 0.0 seconds, the electrical overstress circuit 130 has just started, and the voltage level is still high, approximately close to 7 volts.

After time to, the clamping of the electrical overstress circuit 130 can control the positive voltage level of the waveform to be below a voltage V1, and control the negative voltage level of the waveform to be above a voltage V2. Therefore, the clamping of the electrical overstress circuit 130 can control the waveform between the voltages V1 and V2 to prevent the voltage at the node α in FIG. 1 from becoming too strong and damaging the amplifier circuit 120. In an embodiment, time t0 can be less than or equal to 100 nanoseconds (ns).

In summary, using the amplification circuit 100 and the electrical overstress circuit 130 provided in the embodiments can effectively protect the circuit, reducing the incidence of circuit component damage. It also lowers the parasitic capacitance of the electrical overstress circuit 130, preventing unexpected increases in the noise figure (NF). Therefore, it can improve the performance and reliability of the circuit.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit, comprising:
an input terminal configured to receive an input signal;
an output terminal configured to output an output signal corresponding to the input signal;
a first path circuit comprising:
a co-design circuit comprising:
a first terminal coupled to the input terminal;
a second terminal; and
a first matching element comprising a first terminal coupled to the first terminal of the co-design circuit, and a second terminal coupled to the second terminal of the co-design circuit;
an amplifier circuit configured to amplify the input signal, the amplifier circuit comprising a first terminal coupled to the second terminal of the co-design circuit, and a second terminal coupled to the output terminal;
a second matching element comprising a first terminal coupled to the first terminal of the amplifier circuit, and a second terminal coupled to a reference voltage terminal; and
an electrical overstress circuit comprising a first terminal coupled between the second terminal of the co-design circuit and the first terminal of the amplifier circuit, and a second terminal coupled to the reference voltage terminal, wherein the first terminal of the electrical overstress circuit is coupled between the second terminal of the co-design circuit and the first terminal of the second matching element; and
a second path circuit comprising a first terminal coupled to the input terminal, and a second terminal coupled to the output terminal;
wherein the co-design circuit provides a first impedance in a first mode, and the co-design circuit provides a second impedance in a second mode.

2. The amplification circuit of claim 1, wherein the first matching element comprises a capacitor, and the second matching element comprises an inductor.

3. The amplification circuit of claim 1, wherein a signal entering the first path circuit has a first power, and another signal entering the second path circuit has a second power, and the first power is less than the second power.

4. The amplification circuit of claim 1, wherein the first matching element and the second matching element form a part of an input impedance matching circuit of the amplifier circuit.

5. The amplification circuit of claim 1, wherein:
the co-design circuit further comprises a third matching element and a first switch,
wherein the third matching element and the first switch are coupled in series between the first terminal and the second terminal of the co-design circuit.

6. The amplification circuit of claim 5, wherein the third matching element comprises an inductor.

7. The amplification circuit of claim 5, wherein the co-design circuit further comprises:
a second switch comprising a first terminal coupled to the second terminal of the co-design circuit, and a second terminal coupled to the reference voltage terminal.

8. The amplification circuit of claim 7, wherein:
when the first path circuit is enabled, in an amplification mode, the first switch is turned off, the second switch is turned off, and the input signal is transmitted through the first path circuit and processed to generate the output signal, wherein in the amplification mode, the co-design circuit is in the second mode.

9. The amplification circuit of claim 8, wherein:
when the second path circuit is enabled, in a bypass mode or a power amplification mode, the first switch is turned on, the second switch is turned on, and the input signal is transmitted through the second path circuit and processed to generate the output signal, wherein in the bypass mode, the co-design circuit is in the second mode.

10. The amplification circuit of claim 1, wherein the first impedance is less than the second impedance.

11. The amplification circuit of claim 5, wherein the co-design circuit further comprises a second switch, and the second switch comprises:
a first terminal coupled to the second terminal of the co-design circuit;
a second terminal coupled to the reference voltage terminal; and
x transistors, each transistor of the x transistors comprising a first terminal and a second terminal, wherein a second terminal of an i-th transistor of the x transistors is coupled to a first terminal of an (i+1)-th transistor of the x transistors, i and x are positive integers, and 0<i<x.

12. The amplification circuit of claim 5, wherein the electrical overstress circuit further comprises:
a transistor comprising a first terminal coupled to the first terminal of the electrical overstress circuit, a second terminal directly coupled to the reference voltage terminal, and a control terminal coupled to the reference voltage terminal or coupled to the reference voltage terminal through a resistor.

13. The amplification circuit of claim 12, wherein the co-design circuit further comprises a second switch, and the second switch comprises:
a first terminal coupled to the second terminal of the co-design circuit;
a second terminal coupled to the reference voltage terminal; and
a transistor;
wherein the transistor of the second switch has a first size, the transistor of the electrical overstress circuit has a second size larger than the first size.

14. The amplification circuit of claim 13, wherein:
the transistor of the electrical overstress circuit and the transistor of the second switch have a same width-to-length ratio;
the transistor of the electrical overstress circuit is formed by p semiconductor components;
the transistor of the second switch is formed by q semiconductor components;
each semiconductor component of the transistor of the electrical overstress circuit is same as each semiconductor component of the transistor of the second switch; and
p and q are integers greater than 0, and p>q.

15. The amplification circuit of claim 13, wherein:
the second switch comprises x transistors;
each transistor of the x transistors comprises a first terminal and a second terminal;
a second terminal of an i-th transistor of the x transistors is coupled to the first terminal of an (i+1)-th transistor of the x transistors;
i and x are positive integers, and 0<i<x;
the transistor of the electrical overstress circuit comprises y transistors;
each transistor of the y transistors comprises a first terminal and a second terminal;
the second terminal of a j-th transistor of the y transistors is coupled to the first terminal of a (j+1)-th transistor of the y transistors;
j and y are positive integers, 0<j<y, and x>y.

16. The amplification circuit of claim 1, wherein:
the second path circuit further comprises an attenuation circuit configured to attenuate the input signal; and
the attenuation circuit comprises a first terminal coupled to the first terminal of the second path circuit, and a second terminal coupled to the second terminal of the second path circuit.

17. The amplification circuit of claim 1, wherein:
the second path circuit further comprises a power amplification circuit configured to amplify the input signal; and
the power amplification circuit comprises a first terminal coupled to the first terminal of the second path circuit, and a second terminal coupled to the second terminal of the second path circuit.

18. The amplification circuit of claim 1, wherein the electrical overstress circuit further comprises:
a transistor comprising a first terminal coupled to the first terminal of the electrical overstress circuit, a second terminal, and a control terminal;
a diode comprising an anode terminal coupled to the second terminal of the transistor, and a cathode terminal coupled to the reference voltage terminal; and
a resistor comprising a first terminal and a second terminal, wherein a body terminal of the transistor of the electrical overstress circuit is coupled to the reference voltage terminal through the resistor.

19. The amplification circuit of claim 1, wherein the electrical overstress circuit further comprises:
a first diode string, comprising K diodes, wherein a cathode terminal of a k-th diode of the K diodes is coupled to an anode terminal of a (k+1)-th diode of the K diodes, an anode terminal of a first diode of the K diodes is coupled to the first terminal of the electrical overstress circuit, and a cathode terminal of a K-th diode of the K diodes is coupled to the second terminal of the electrical overstress circuit, K and k are integers, 1≤k≤(K−1); and
a second diode string, comprising R diodes, wherein a cathode terminal of an r-th diode of the R diodes is coupled to an anode terminal of an (r+1)-th diode of the R diodes, an anode terminal of a first diode of the R diodes is coupled to the second terminal of the electrical overstress circuit, and a cathode terminal of an R-th diode of the R diodes is coupled to the first terminal of the electrical overstress circuit;
wherein R and r are integers, 1≤r≤(R−1).

20. A control method for an amplification circuit, the amplification circuit comprising an input terminal, an output terminal, a first path circuit and a second path circuit, the first path circuit comprising a co-design circuit, an electrical overstress circuit and an amplifier circuit, the control method comprising:
using the input terminal to receive an input signal;
using the output terminal to output an output signal corresponding to the input signal;
turning off a switch of the co-design circuit to control the amplification circuit to enter an amplification mode to transmit and process the input signal through the co-design circuit to generate the output signal, wherein a matching element of the co-design circuit is used to provide a matching impedance to the amplifier circuit;
turning on the switch of the co-design circuit to control the amplification circuit to enter a bypass mode or a power amplification mode to transmit and process the input signal through the second path circuit to generate the output signal, wherein the matching element of the co-design circuit resonates to provide a high impedance; and
turning on the electrical overstress circuit to control the amplification circuit to enter an electrical overstress mode to transmit a signal to a reference voltage terminal through the co-design circuit.
